(19) United States
(12) Patent Application Publication
(10) Pub. No.: US 2022/0302087 A1
(43) Pub. Date: Sep. 22, 2022

(54) SEMICONDUCTOR PACKAGE

(71) Applicant: SAMSUNG ELECTRONICS CO., LTD., SUWON-SI (KR)

(72) Inventors: DONGJOO CHOI, SEOUL (KR); SEUNGDUK BAEK, HWASEONG-SI (KR)

(21) Appl. No.: 17/509,610

(22) Filed: Oct. 25, 2021

(30) Foreign Application Priority Data
Mar. 16, 2021 (KR) 10-2021-0034209

(51) Int. Cl. H01L 25/065; H01L 23/00; H01L 23/538; H01L 23/367

(52) U.S. Cl. CPC H01L 25/0657; H01L 24/14; H01L 23/5386; H01L 23/367

(57) ABSTRACT

A semiconductor package includes second semiconductor chip stacked on the first semiconductor chip, a chip adhesive layer between the first and second semiconductor chips, a quadrangular signal pillar and a quadrangular center dummy pillar between a central portion of the second semiconductor chip and the first semiconductor chip, an elliptical corner dummy pillar between a corner portion of the second semiconductor chip and the first semiconductor chip, a signal bump between the signal pillar and the first semiconductor chip, a center dummy bump between the center dummy pillar and the first semiconductor chip and a corner dummy bump section between the corner dummy pillar and the first semiconductor chip. The signal pillar and the signal bump provide an electrical path between the second semiconductor chip and the first semiconductor chip, the center dummy pillar and the center dummy bump provide one thermal path between the second semiconductor chip and the first semiconductor chip, and the corner dummy pillar and the corner dummy bump provide another thermal path between the second semiconductor chip and the first semiconductor chip.

### CROSS-REFERENCE TO RELATED APPLICATION

This U.S. nonprovisional application claims priority under 35 U.S.C. § 119 to Korean Patent Application No. 10-2021-0034209 filed on Mar. 16, 2021 in the Korean Intellectual Property Office, the subject matter of which is hereby incorporated by reference.

### BACKGROUND

The inventive concept relates generally to semiconductor packages and semiconductor packaging techniques. More particularly, the inventive concept relates to semiconductor packages including vertically stacked semiconductor chips.

As miniaturization, multifunctionality, and high performance of electronic products are increasingly required, semiconductor packages are required that are highly integrated, provide excellent performance and operate at high speed. In order to satisfy this constellation of requirements, semiconductor packages may include semiconductor chips, wherein one semiconductor chip is stacked on another semiconductor chip. Of further note, some approaches to fabricating semiconductor packages including stacked semiconductor chips use so-called “bumps,” instead of conductive wires, to electrically connect the stacked semiconductor chips.

However, a semiconductor package including stacked semiconductor chips may generate troublesome amounts of thermal energy (e.g. heat) that must be effectively managed in order to ensure reliable operation of the semiconductor package.

### SUMMARY

Embodiments of the inventive concept provide semiconductor packages including stacked semiconductor chips exhibiting improved heat management (e.g., dissipation).

In some embodiments, a semiconductor package may include a first semiconductor chip, and a second semiconductor chip stacked on the first semiconductor chip, a chip adhesive layer between the first semiconductor chip and the second semiconductor chip, a signal pillar having a quadrangular horizontal cross-section and a center dummy pillar having a quadrangular horizontal cross-section between a central portion of the second semiconductor chip and the first semiconductor chip, a corner dummy pillar having an elliptical horizontal cross-section between a corner portion of the second semiconductor chip and the first semiconductor chip, a signal bump between the signal pillar and the first semiconductor chip, a center dummy bump between the center dummy pillar and the first semiconductor chip, and a corner dummy bump section between the corner dummy pillar and the first semiconductor chip, wherein the signal pillar and the signal bump provide an electrical path between the second semiconductor chip and the first semiconductor chip, the center dummy pillar and the center dummy bump provide one thermal path between the second semiconductor chip and the first semiconductor chip, and the corner dummy pillar and the corner dummy bump provide another thermal path between the second semiconductor chip and the first semiconductor chip.

In some embodiments, a semiconductor package may include a first semiconductor chip and a second semiconductor chip stacked on the first semiconductor chip, a chip adhesive layer between the first semiconductor chip and the second semiconductor chip, signal pillars two-dimensionally arranged between a central portion of the second semiconductor chip and the first semiconductor chip, center dummy pillars two-dimensionally arranged between the central portion of the second semiconductor chip and the first semiconductor chip, corner dummy pillars two-dimensionally arranged between a corner portion of the second semiconductor chip and the first semiconductor chip, signal bumps respectively between the signal pillars and the first semiconductor chip, center dummy bumps respectively between the center dummy pillars and the first semiconductor chip, and corner dummy bumps respectively between the corner dummy pillars and the first semiconductor chip, wherein each of the signal pillars with one of the signal bumps provides an electrical paths between the second semiconductor chip and the first semiconductor chip, each one of the center dummy pillars with one of the center dummy bumps provides a respective thermal path between the second semiconductor chip and the first semiconductor chip, each one of the corner dummy pillars with one of the corner dummy bumps provides a respective thermal path between the second semiconductor chip and the first semiconductor chip, each of the signal pillars and each of the center dummy pillars has a quadrangular horizontal cross-section, and each of the corner dummy pillars has an elliptical horizontal cross-section.

In some embodiments, a semiconductor package may include a first semiconductor chip and a second semiconductor chip stacked on the first semiconductor chip, a chip adhesive layer between the first semiconductor chip and the second semiconductor chip, a signal pillar having an elliptical horizontal cross-section and a center dummy pillar having a quadrangular horizontal cross-section between a central portion of the second semiconductor chip and the first semiconductor chip, a corner dummy pillar having an elliptical horizontal cross-section between a corner portion of the second semiconductor chip and the first semiconductor chip, a signal bump between the signal pillar and the first semiconductor chip, a center dummy bump between the center dummy pillar and the first semiconductor chip, a corner dummy bump between the corner dummy pillar and the first semiconductor chip, and a molding layer covering a portion of an upper surface of the first semiconductor chip and sidewalls of the second semiconductor chip, wherein the signal pillar and the signal bump provide an electrical path between the second semiconductor chip and the first semiconductor chip, the center dummy pillar and the center dummy bump provide one thermal path between the second semiconductor chip and the first semiconductor chip, and the corner dummy pillar and the corner dummy bump provide another thermal path between the second semiconductor chip and the first semiconductor chip.

### BRIEF DESCRIPTION OF THE DRAWINGS

The making and use of the inventive concept may be more clearly understood upon consideration of the following detailed description together with the accompanying drawings in which:

FIG. 1 is a cross-sectional view illustrating a semiconductor package according to embodiments of the inventive concept;

FIG. 2 is a cross-sectional view taken along line A-A′ of FIG. 1, FIG. 3 is a cross-sectional view taken along line B-B′ of FIG. 1, FIG. 4 is a cross-sectional view taken along line C-C′ of FIG. 1, and FIG. 5 is a cross-sectional view taken along line D-D′ of FIG. 1;

FIGS. 6 and 7 are respective cross-sectional views illustrating semiconductor packages according to embodiments of the inventive concept; and

FIGS. 8A, 8B, 8C, 8D, 8E, 8F, 8G, 8H and 8I (hereafter collectively, “FIGS. 8A to 8I”) are related cross-sectional views illustrating in one example a method of manufacturing a semiconductor package according to embodiments of the inventive concept.

### DETAILED DESCRIPTION

Throughout the written description and drawings, like reference numbers and labels are used to denote like or similar elements and/or features. Throughout the written description certain geometric terms may be used to highlight relative relationships between elements, components and/or features with respect to certain embodiments of the inventive concept. Those skilled in the art will recognize that such geometric terms are relative in nature, arbitrary in descriptive relationship(s) and/or directed to aspect(s) of the illustrated embodiments. Geometric terms may include, for example: height/width; vertical/horizontal; top/bottom; higher/lower; closer/farther; thicker/thinner; proximate/distant; above/below; under/over; upper/lower; center/side; surrounding; on; overlay/underlay; etc.

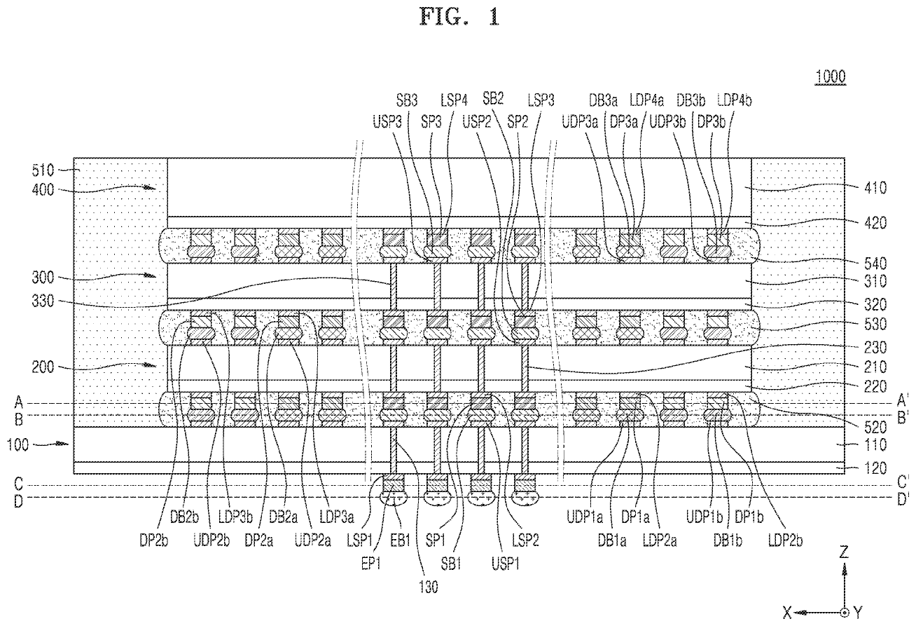

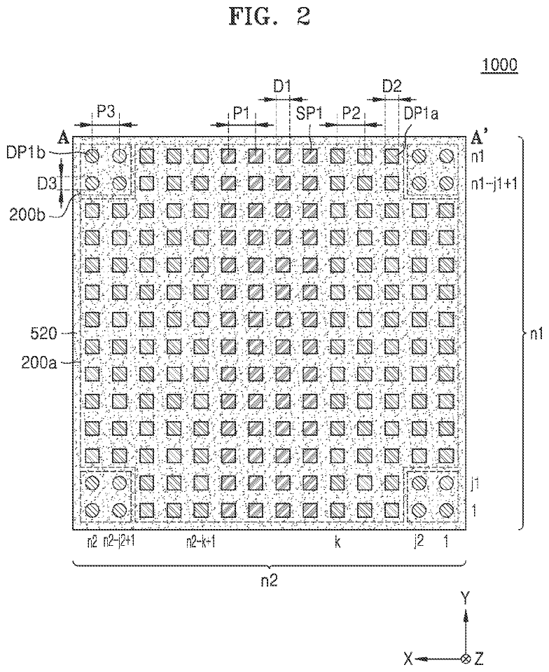

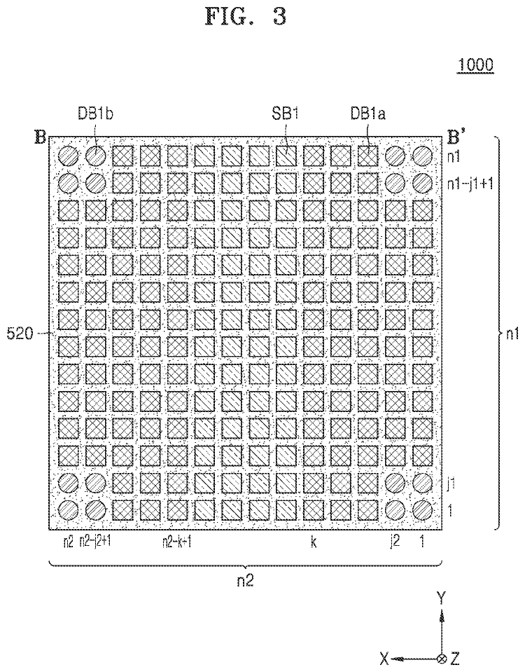

Figure (FIG. 1 is a cross-sectional view illustrating a semiconductor package 1000 according to embodiments of the inventive concept; FIG. 2 is a cross-sectional view taken along line A-A′ of FIG. 1; FIG. 3 is a cross-sectional view taken along line B-B′ of FIG. 1; FIG. 4 is a cross-sectional view taken along the line C-C′ of FIG. 1; and FIG. 5 is a cross-sectional view taken along line D-D′ of FIG. 1.

Referring collectively to FIGS. 1, 2, 3, 4 and 5 (hereafter collectively, “FIGS. 1 to 5”), the semiconductor package 1000 may include a plurality of semiconductor chips stacked one on top of the other in a vertical direction (e.g., the Z direction). Hereafter, this arrangement of semiconductor chips will described as one semiconductor chip being “stacked on” another semiconductor chip. In the illustrated example of FIGS. 1 to 5, the semiconductor package 1000 includes a first semiconductor chip 100, a second semiconductor chip 200 stacked on the first semiconductor chip 100, a third semiconductor chip 300 stacked on the second semiconductor chip 200, and a fourth semiconductor chip 400 stacked on the third semiconductor chip 300.

In some embodiments, horizontal area of each of the second, third and fourth semiconductor chips 200, 300 and 400 may be substantially the same. In some embodiments, the horizontal area of the first semiconductor chip 100 may be greater than that of the second, third and fourth semiconductor chips 200, 300 and 400. In this context, the “horizontal area” of the respective semiconductor chips may be defined by a first horizontal direction (e.g., the X direction) and a second horizontal direction (e.g., the Y direction), each intersecting the vertical direction.

In some embodiments, the first, second, third and fourth semiconductor chips 100, 200, 300 and 400 (hereafter collectively, “first to fourth semiconductor chips 100 to 400”) may be semiconductor chips of same type (e.g., memory chips, such as one or more of dynamic random access memory (RAM) (DRAM), static RAM (SRAM), flash memory, phase-change RAM (PRAM), magneto-resistive RAM (MRAM), ferroelectric RAM (FeRAM), resistive RAM (RRAM), etc. Alternately, two or more of the first to fourth semiconductor chips 100 to 400 may be semiconductor chips of different type (e.g., a logic chip and a memory chip). For example, the first semiconductor chip 100 may be a logic chip, and the second, third and fourth semiconductor chips 200, 300 and 400 may be memory chips. In this regard, a logic chip may include at least one of a central processing unit (CPU), a graphics processing unit (GPU), an application processor (AP), etc.

In some embodiments, the first to fourth semiconductor chips 100 to 400 may be implemented according to a technical standard describing a high bandwidth memory (HBM) or a hybrid memory cube (HMC). In this case, the first semiconductor chip, the lowest chip of the first to fourth semiconductor chips 100 to 400 may function as a buffer die, whereas the second to fourth semiconductor chips 200 to 400 may function as core dies. For example, the buffer die may also be referred to as an interface die, a base die, a logic die, a master die, and the like. And the core die may be referred to as a memory die, a slave die, or the like.

Those skilled in the art will recognize that the illustrated example of FIGS. 1 to 5 is just that: an example. More or fewer semiconductor chips of various size and/or type may be variously stacked in a semiconductor package according to embodiments of the inventive concept.

However, in FIGS. 1 to 5, the first semiconductor chip 100 may include a first semiconductor substrate 110, a first semiconductor device layer 120, a first lower signal pad LSP1, a first upper signal pad USP1, a first upper signal pad USP1, a first upper center dummy pad UDP1a, a first upper corner dummy pad UDP1b, and a first through electrode 130.

The first semiconductor substrate 110 may include a semiconductor material such as a group IV semiconductor material, a group III-V semiconductor material, or a group II-VI semiconductor material. The group IV semiconductor material may include, for example, silicon (Si), germanium (Ge), or silicon (Si)-germanium (Ge). The group III-V semiconductor material may include, for example, gallium arsenide (GaAs), indium phosphate (InP), gallium phosphate (GaP), indium arsenide (InAs), indium antimony (InSb), or indium gallium arsenide (InGaAs). The group II-VI semiconductor material may include, for example, zinc telluride (ZnTe) or cadmium sulfide (CdS).

The first semiconductor device layer 120 may include a multiplicity of individual elements of various types and an interlayer insulating layer. The individual elements may include, for example, various active and passive elements, such as transistors, capacitors, resistors, and the like. For example, the first semiconductor device layer 120 may include a logic circuit, flash memory, DRAM, SRAM, EEPROM, PRAM, MRAM, RRAM, a CMOS imaging sensor (CIS), a micro-electro-mechanical system (MEMS), etc.

The first upper signal pad USP1, the first upper center dummy pad UDP1a, and the first upper corner dummy pad UDP1b may be arranged on the top surface of the first semiconductor chip 100. The first lower signal pad LSP1 may be disposed on the lower surface of the first semiconductor chip 100. The first upper signal pad USP1, the first upper center dummy pad UDP1a, the first upper corner dummy pad UDP1b, and the first lower signal pad LSP1 may include aluminum (Al), copper (Cu), nickel (Ni), tungsten (W), platinum (Pt), gold (Au), or a combination thereof.

The first through electrode 130 may at least partially penetrate the first semiconductor substrate 110 in the vertical direction, and may at least partially further penetrate the first semiconductor device layer 120 in the vertical direction. The first through electrode 130 may be configured to electrically connect the first upper signal pad USP1 and the first lower signal pad LSP1 to each other. The first through electrode 130 may not be connected the first upper center dummy pad UDP1a and the first upper corner dummy pad UDP1b.

The first through electrode 130 may include a pillar-shaped buried conductive layer extending in the vertical direction and a cylindrical conductive barrier layer surrounding a sidewall of the buried conductive layer. The buried conductive layer may include, for example, copper (Cu), tungsten (W), nickel (Ni), cobalt (Co), or a combination thereof. The conductive barrier layer may include titanium (Ti), titanium nitride (TiN), tantalum (Ta), tantalum nitride (TaN), or a combination thereof. A via insulating layer may be between the first semiconductor substrate 110 and the first through electrode 130. The via insulating layer may include silicon oxide, silicon nitride, a polymer, or a combination thereof.

An external pillar EP1 may be disposed on the first lower signal pad LSP1. An external bump EB1 may be disposed on the external pillar EP1. The external pillar EP1 and the external bump EB1 may connect the semiconductor package 1000 to an external substrate or an interposer. The external pillar EP1 and the external bump EB1 may receive a data signal, a control signal, a power signal, or a ground signal from an external source, and/or provide (or output) data stored in the first to fourth semiconductor chips 100 to 400 to an external source. The external pillar EP may include, for example, nickel (Ni), copper (Cu), palladium (Pd), platinum (Pt), gold (Au), or a combination thereof. The external bump EB1 may include, for example, tin (Sn), indium (In), bismuth (Bi), antimony (Sb), copper (Cu), silver (Ag), gold (Au), zinc (Zn), lead (Pb), or a combination thereof.

The external pillars EP1 and the external bumps EB1 may have a shape and/or a layout arrangement defined in accordance with a Joint Electron Device Engineering Council (JEDEC) technical standard. For example, with reference to FIG. 4, a “horizontal cross-section” (e.g., a cross-section defined by an arbitrary horizontal plane) of the external pillar EP1 may be elliptical (e.g., oval or circular). That is, the external pillar EP1 may have an elliptical horizontal cross-section.

Here, the external pillars EP1 may be arranged in a two-dimensional array having n1 rows and n2-2k columns, where ‘n1,’ ‘n2,’ and ‘k’ are natural numbers. Rows of the two-dimensional array extend in the first horizontal direction and are spaced apart in the second horizontal direction, and columns of the two-dimensional array extend in the second horizontal direction and are spaced apart in the first horizontal direction.

Similarly, as illustrated in FIG. 5, a horizontal cross-section the external bump EB1 may be elliptical. Additionally, because the external bumps EB1 respectively contact the external pillars EP1, the external bumps may be similarly arranged (e.g., in the two-dimensional array including n1 rows and n2-2k columns).

The second semiconductor chip 200 stacked on the first semiconductor chip 100 may analogously include a second semiconductor substrate 210, a second semiconductor device layer 220, a second lower signal pad LSP2, a second lower center dummy pad LDP2a, a second lower corner dummy pad LDP2b, a second upper signal pad USP2, a second upper center dummy pad UDP2a, and a second upper corner dummy pad UDP2b, and a second through electrode 230. Here, the second semiconductor substrate 210 may be the same as the first semiconductor substrate 110, and the second semiconductor device layer 220 may be the same as the first semiconductor device layer 120.

The second lower signal pad LSP2, the second lower center dummy pad LDP2a, and the second lower corner dummy pad LDP2b may be disposed on the lower surface of the second semiconductor chip 200. The second upper signal pad USP2, the second upper center dummy pad UDP2a, and the second upper corner dummy pad UDP2b may be disposed on the top surface of the second semiconductor chip 200. The second lower signal pad LSP2, the second lower center dummy pad LDP2a, the second lower corner dummy pad LDP2b, the second upper signal pad USP2, the second upper center dummy pad UDP2a, and the second upper corner dummy pad UDP2b may include aluminum (Al), copper (Cu), nickel (Ni), tungsten (W), platinum (Pt), gold (Au), or a combination thereof.

The second through electrode 230 may at least partially penetrate the second semiconductor substrate 210 in the vertical direction, and may further penetrate the second semiconductor device layer 220 at least partially in the vertical direction. The second through electrode 230 may be configured to electrically connect the second lower signal pad LSP2 and the second upper signal pad USP2 to each other. The second through electrode 230 may not be connected to the second lower center dummy pad LDP2a, the second lower corner dummy pad LDP2b, the second upper center dummy pad UDP2a, and the second upper corner dummy pad UDP2b. Here, the second through electrode 230 may be substantially the same as the first through electrode 130.

A first signal pillar SP1, a first center dummy pillar DP1a, and a first corner dummy pillar DP1b may be disposed between the second semiconductor chip 200 and the first semiconductor chip 100. The first signal pillar SP1 may be disposed between the first upper signal pad USP1 of the first semiconductor chip 100 and the second lower signal pad LSP2 of the second semiconductor chip 200. The first center dummy pillar DP1a may be disposed between the first upper center dummy pad UDP1a of the first semiconductor chip 100 and the second lower center dummy pad LDP2a of the second semiconductor chip 200. The first corner dummy pillar DP1b may be disposed between the first upper corner dummy pad UDP1b of the first semiconductor chip 100 and the second lower corner dummy pad LDP2b of the second semiconductor chip 200.

A first signal bump SB1 may be disposed between the first signal pillar SP1 and the first upper signal pad USP1 of the first semiconductor chip 100. A first center dummy bump DB1a may be disposed between the first center dummy pillar DP1a and the first upper center dummy pad UDP1a of the first semiconductor chip 100. A first corner dummy bump DB1b may be disposed between the first corner dummy pillar DP1b and the first upper corner dummy pad UDP1b of the first semiconductor chip 100.

A first chip adhesive layer 520 may be disposed between the first semiconductor chip 100 and the second semiconductor chip 200. The first chip adhesive layer 520 may substantially surround the first signal pillar SP1, the first signal bump SB1, the first center dummy pillar DP1a, the first center dummy bump DB1a, the first corner dummy pillar DP1b, and the first corner dummy bump DB1b. The first chip adhesive layer 520 may include, for example, a non-conductive film (NCF), a non-conductive paste (NCP), a molded underfill (MUF), an insulating polymer, an epoxy resin, etc.

The first signal pillar SP1 and the first signal bump SB1 may provide an electrical path between the second semiconductor chip 200 and the first semiconductor chip 100. That is, the first semiconductor chip 100 may be electrically connected to the second semiconductor chip 200 through the first signal pillar SP1 and the first signal bump SB1. The first center dummy pillar DP1a, the first center dummy bump DB1a, the first corner dummy pillar DP1b, and the first corner dummy bump DB1b are configured to provide a thermal path between the first semiconductor chip 100 and the second semiconductor chip 200. That is, the first center dummy pillar DP1a, the first center dummy bump DB1a, the first corner dummy pillar DP1b, and the first corner dummy bump DB1b do not transmit signals, but may transmit heat generated in the first to fourth semiconductor chips 100 to 400 to the outside. Accordingly, the semiconductor package 1000 may exhibit improved heat dissipation performance by including the first center dummy pillar DP1a, the first center dummy bump DB1a, the first corner dummy pillar DP1b, and the first corner dummy bump DB1b.

The first signal pillar SP1, the first center dummy pillar DP1a, and the first corner dummy pillar DP1b may include, for example, nickel (Ni), copper (Cu), palladium (Pd), platinum (Pt), gold (Au), or a combination thereof. The first signal bump SB1, the first center dummy bump DB1a, and the first corner dummy bump DB1b may include, for example, tin (Sn), indium (In), bismuth (Bi), antimony (Sb), copper (Cu), silver (Ag), gold (Au), zinc (Zn), lead (Pb), or a combination thereof.

As shown in FIG. 2, the first signal pillar SP1 and the first center dummy pillar DP1a may be disposed between a central portion 200a of the second semiconductor chip 200 and the first semiconductor chip 100. The first corner dummy pillar DP1b may be disposed between a corner portion 200b of the second semiconductor chip 200 and the first semiconductor chip 100

As also shown in FIG. 2, the horizontal cross-section of the first signal pillar SP1 may be quadrangular (e.g., square or rectangular). That is, the horizontal cross-section of the first signal pillar SP1 may be an angled or a rounded-corner quadrangle. Further, the horizontal cross-section of the first center dummy pillar DP1a may be quadrangular.

Because the area of a quadrangle having a side length of ‘A’ will be A², and the area of a circle having a diameter ‘A’ will be (π/4)A², the area of the quadrangle is greater than the area of the circle for a same side/diameter value A. Therefore, when the respective, horizontal cross-sections of the first signal pillar SP1 and the first center dummy pillar DP1a are quadrangular, the respective cross-sectional areas for the first signal pillar SP1 and the first center dummy pillar DP1a will be greater than comparative, circular cross-sectional areas. And this relatively greater cross-sectional area results in relatively greater thermal conduction which provides relatively greater heat dissipation (or heat exhaust) through the first signal pillar SP1 and the first center dummy pillar DP1a, as compared with comparative signal pillars and the center dummy pillars having circular horizontal cross-sections.

In contrast, a horizontal cross-section of the first corner dummy pillar DP1b may be elliptical. Accordingly, when the first chip adhesive layer 520 is formed (e.g., deposited or flowed), it is relatively easy for the first chip adhesive layer 520 fill (or in-fill) space(s) between the central portion 200a of the second semiconductor chip 200 and the first semiconductor chip 100. However, it may be difficult for the first chip adhesive layer 520 to fill between the corner portion 200b of the second semiconductor chip 200 and the first semiconductor chip 100.

Thus, the elliptical horizontal cross-section of the first corner dummy pillar DP1b, as compared with a quadrangular horizontal cross-section for the first corner dummy pillar DP1b, provides an improved flow path (or physical topography) for the first chip adhesive layer 520 around the first corner dummy pillar DP1b, so that the first chip adhesive layer 520 may completely fill a space between the corner portion 200b of the second semiconductor chip 200 and the first semiconductor chip 100, thereby substantially surrounding the first corner dummy pillar DP1b.

In some embodiments, a first width D1 (as measured in the first horizontal direction) of one side of the first signal pillar SP1 may be equal to a second width D2 of one side of the first center dummy pillar DP1a. In addition, the second width D2 of the first center dummy pillar DP1a may be equal to a diameter D3 of the corner dummy pillar DP1b. Thus, by defining equal side/diameter dimensions for the first signal pillar SP1, the first center dummy pillar DP1a, and the first corner dummy pillar DP1b, an arrangement of the first signal pillar SP1a, the first center dummy pillar DP1a, and the first corner dummy pillar DP1b may be readily realized.

In some embodiments, the first width D1 of one side of the first signal pillar SP1, the second width D2 of one side of the first center dummy pillar DP1a, and the diameter D3 of the first corner dummy pillar DP1b may range (equally) from between about 5 μm to about 20 μm. In this regard, if the first width D1, the second width D2 and diameter D3 are greater than about 20 μm, the respective areas occupied by the corresponding elements on the second semiconductor chip 200 may be come too large. However, if the first width D1, the second width D2, and the diameter D3 are less than about 5 μm, the resulting electrical resistance of the first signal pillar SP1 may be too high.

Yet, because the area of a quadrangle having a side length A is greater than the area of a circle having a diameter A, the resulting cross-sectional area of the first signal pillar SP1 will be greater than the resulting cross-sectional area of the first corner dummy pillar DP1b. And the resulting cross-sectional area of the first center dummy pillar DP1a may be greater than the cross-sectional area of the first corner dummy pillar DP1b.

As variously shown in FIGS. 1 to 5, first signal pillars SP1 may be two-dimensionally arranged at regular intervals, first center dummy pillars DP1a may be two-dimensionally arranged at regular intervals, and first corner dummy pillars DP1b may be two-dimensionally arranged at regular intervals.

In some embodiments, a first pitch P1 for the first signal pillars SP1 may be equal to a second pitch P2 for the first center dummy pillars DP1a. Also, the second pitch P2 of the first center dummy pillars DP1a may be equal to a third pitch P3 for the first corner dummy pillars DP1b. Thus, by defining respective pitches for the first signal pillar SP1, the first center dummy pillar DP1a, and the first corner dummy pillar DP1b to be substantially equal, the arrangement of the first signal pillar SP1, the first center dummy pillar DP1a, and the first corner dummy pillar DP1b may be readily realized.

In some embodiments, each of the first pitch P1 for the first signal pillars SP1, the second pitch P2 for the first center dummy pillars DP1a, and the third pitch P3 for the first corner dummy pillars DP1b may range (equally) from about 10 μm to about 40 μm.

In some embodiments, as shown in FIG. 2, the first signal pillars SP1, the first center dummy pillars DP1a, and the first corner dummy pillars DP1b may be arranged in an array having n1 rows and n2 columns, wherein the rows extend in the first horizontal direction and are spaced apart in the second horizontal direction, and the columns of the two-dimensional array extend in the second horizontal direction and are spaced apart in the first horizontal direction. Here, ‘n1’ and ‘n2’ are natural numbers.

In some embodiments, the first signal pillars SP1 may be arranged in k+1 to (n2-k)th columns of an array, where ‘k’ is a natural number. That is, the first signal pillars SP1 may be arranged in a sub-array having n1 rows and n2-2k columns. The first center dummy pillars DP1a and the first corner dummy pillars DP1b may be arranged in 1st to kth columns and n2-k+1 to n2-th columns of the array. That is, the first center dummy pillars DP1a and the first corner dummy pillars DP1b may be arranged in two sub-arrays each having n1 rows and k columns.

In some embodiments, the first corner dummy pillars DP1b may be arranged at positions of an m1-th row and an m2-th column of the array. Here, m1 may be 1 to j1 or n1-j1+1 to n1, and m2 may be 1 to j2 or n2-j2+1, where ‘m1’ and ‘m2’ are natural numbers. That is, the first corner dummy pillars DP1b may be respectively positioned at four corners of the array, and may be arranged in four sub-arrays each having j1 rows and j2 columns.

As shown in FIG. 3, in some embodiments, a horizontal cross-section of the first signal bump SB1 may be a quadrangle. A horizontal cross-section of the first center dummy bump DB1a may be a quadrangle. And a horizontal cross-section of the first corner dummy bump DB1b may be elliptical.

When the respective horizontal cross-sections of the first signal bump SB1 and the first center dummy bump DB1a are quadrangular, the resulting cross-sectional areas for the first signal bump SB1 and the first center dummy bump DB1a may be comparatively increased, such that heat dissipation through the first signal bump SB1 and the first center dummy bump DB1a may be improved. Further, when the cross-sectional area of the first corner dummy bump DB1b is elliptical, the flow of the first chip adhesive layer 520 around the first corner dummy bump DB1b is better facilitated, such that the first chip adhesive layer 520 may fill a space between the corner portion 200b of the second semiconductor chip 200 and the first semiconductor chip 100 and substantially surround the first corner dummy bump DB1b.

Because the first signal bumps SB1, the first center dummy bumps DB1a, and the first corner dummy bumps DB1b respectively contact the first signal pillars SP1, the first center dummy pillars DP1a, and the first corner dummy pillars DP1b may respectively have substantially the same arrangement as first signal pillars SP1, the first center dummy pillars DP1a, and the first corner dummy pillars DP1b.

For example, as shown in FIG. 3, the first signal bumps SB1, the first center dummy bumps DB1a, and the first corner dummy bumps DB1b may be arranged in an array having n1 rows and n2 columns, wherein the rows of the array extend in the first horizontal direction and are spaced apart in the second horizontal direction, and the columns of the two-dimensional array extend in a second horizontal direction and are spaced apart in a first horizontal direction. Here, ‘n1’ and ‘n2’ are natural numbers.

In some embodiments, the first signal bumps SB1 may be arranged in k+1 to n2-k th columns of the array, where k is a natural number. That is, the first signal bumps SB1 may be arranged in a sub-array having n1 rows and n2-2k columns. The first center dummy bumps DB1a and the first corner dummy bumps DB1b may be arranged in 1st to k-th columns and n2-k+1 to n2-th columns of the array. That is, the first center dummy bumps DB1a and the first corner dummy bumps DB1b may be arranged in two sub-arrays each having n1 rows and k columns.

In some embodiments, the first corner dummy bumps DB1b may be arranged at positions of an m1-th row and an m2-th column of the array. Here, m1 may be 1 to j1 or n1-j1+1 to n1, and m2 may be 1 to j2 or n2-j2+1, where m1 and m2 are, of course, natural numbers. That is, the first corner dummy bumps DB1b may be respectively positioned at four corners of the array and may be arranged in four sub-arrays each having j1 rows and j2 columns.

The third semiconductor chip 300 stacked on the second semiconductor chip 200 may analogously include a third semiconductor substrate 310, a third semiconductor device layer 320, a third lower signal pad LSP3, a third lower center dummy pad LDP3a, a third lower corner dummy pad LDP3b, a third upper signal pad USP3, a third upper center dummy pad UDP3a, a third upper center dummy pad UDP3b, and a third through electrode 330. Here, the third semiconductor substrate 310 may be the same as the first semiconductor substrate 110, and the third semiconductor device layer 320 may be the same as the first semiconductor device layer 120.

The third lower signal pad LSP3, the third lower center dummy pad LDP3a, and the third lower corner dummy pad LDP3b may be disposed on the lower surface of the third semiconductor chip 300. The third upper signal pad USP3, the third upper center dummy pad UDP3a, and the third upper center dummy pad UDP3b may be disposed on the top surface of the third semiconductor chip 300. The third lower signal pad LSP3, the third lower center dummy pad LDP3a, the third lower corner dummy pad LDP3b, the third upper signal pad USP3, the third upper center dummy pad UDP3a, and the third upper center dummy pad UDP3b may include aluminum (Al), copper (Cu), nickel (Ni), tungsten (W), platinum (Pt), and gold (Au), or a combination thereof.

The third through electrode 330 may at least partially penetrate the third semiconductor substrate 310 in the vertical direction and further at least partially penetrate the third semiconductor device layer 320 in the vertical direction. The third through electrode 330 may be configured to electrically connect the third lower signal pad LSP3 and the third upper signal pad USP3 to each other. The third through electrode 330 may not be connected to the third lower center dummy pad LDP3a, the third lower corner dummy pad LDP3b, the third upper center dummy pad UDP3a, and the third upper corner dummy pad UDP3b.

A second signal pillar SP2, a second center dummy pillar DP2a, and a second corner dummy pillar DP2b may be disposed between the third semiconductor chip 300 and the second semiconductor chip 200. The second signal pillar SP2 may be disposed between the second upper signal pad USP2 of the second semiconductor chip 200 and the third lower signal pad LSP3 of the third semiconductor chip 300. The second center dummy pillar DP2a may be disposed between the second upper center dummy pad UDP2a of the second semiconductor chip 200 and the third lower center dummy pad LDP3a of the third semiconductor chip 300. The second corner dummy pillar DP2b may be disposed between the second upper corner dummy pad UDP2b of the second semiconductor chip 200 and the third lower corner dummy pad LDP3b of the third semiconductor chip 300.

A second signal bump SB2 may be disposed between the second signal pillar SP2 and the second upper signal pad USP2 of the second semiconductor chip 200. A second center dummy bump DB2a may be disposed between the second center dummy pillar DP2a and the second upper center dummy pad UDP2a of the second semiconductor chip 200. A second corner dummy bump DB2b may be disposed between the second corner dummy pillar DP2b and the second upper corner dummy pad UDP2b of the second semiconductor chip 200.

A second chip adhesive layer 530 may be disposed between the second semiconductor chip 200 and the third semiconductor chip 300. The second chip adhesive layer 530 may substantially surround the second signal pillar SP2, the second signal bump SB2, the second center dummy pillar DP2a, the second center dummy bump DB2a, the second corner dummy pillar DP2b, and the second corner dummy bump DB2b.

The second signal pillar SP2 and the second signal bump SB2 may provide an electrical path between the third semiconductor chip 300 and the second semiconductor chip 200. That is, the second semiconductor chip 200 may be electrically connected to the third semiconductor chip 300 through the second signal pillar SP2 and the second signal bump SB2. The second center dummy pillar DP2a, the second center dummy bump DB2a, the second corner dummy pillar DP2b, and the second corner dummy bump DB2b are configured to provide a thermal path between the second semiconductor chip 200 and the third semiconductor chip 300. That is, the second center dummy pillar DP2a, the second center dummy bump DB2a, the second corner dummy pillar DP2b, and the second corner dummy bump DB2b do not transmit signals, but may transmit heat generated in the first to fourth semiconductor chips 100 to 400 to the outside. Accordingly, the semiconductor package 1000 may exhibit improved heat dissipation performance by including the second center dummy pillar DP2a, the second center dummy bump DB2a, the second corner dummy pillar DP2b, and the second corner dummy bump DB2b

Of note, the second signal pillar SP2, the second center dummy pillar DP2a, the second corner dummy pillar DP2b, the second signal bump SB2, the second center dummy bump DB2a, and the second corner dummy bump DB2b may be substantially and respectively the same as the first signal pillar SP1, the first center dummy pillar DP1a, the first corner dummy pillar DP1b, the first signal bump SB1, the first center dummy bump DB1a, and the first corner dummy bump DB1b.

The fourth semiconductor chip 400 stacked on the third semiconductor chip 300 may include a fourth semiconductor substrate 410, a fourth semiconductor device layer 420, a fourth lower signal pad LSP4, a fourth lower center dummy pad LDP4a, and a fourth lower corner dummy pad LDP4b. Here, the fourth semiconductor substrate 410 may be substantially the same as the first semiconductor substrate 110, and the fourth semiconductor device layer 420 may be substantially the same as the first semiconductor device layer 120.

The fourth lower signal pad LSP4, the fourth lower center dummy pad LDP4a, and the fourth lower corner dummy pad LDP4b may be disposed on the lower surface of the fourth semiconductor chip 400. The fourth lower signal pad LSP4, the fourth lower center dummy pad LDP4a, and the fourth lower corner dummy pad LDP4b may include aluminum (Al), copper (Cu), nickel (Ni), tungsten (W), It may include platinum (Pt), gold (Au), or a combination thereof.

A third signal pillar SP3, a third center dummy pillar DP3a, and a third corner dummy pillar DP3b may be disposed between the fourth semiconductor chip 400 and the third semiconductor chip 300. The third signal pillar SP3 may be disposed between the third upper signal pad USP3 of the third semiconductor chip 300 and the fourth lower signal pad LSP4 of the fourth semiconductor chip 400. The third center dummy pillar DP3a may be disposed between the third upper center dummy pad UDP3a of the third semiconductor chip 300 and the fourth lower center dummy pad LDP4a of the fourth semiconductor chip 400. The third corner dummy pillar DP3b may be disposed between the third upper corner dummy pad UDP3b of the third semiconductor chip 300 and the fourth lower corner dummy pad LDP4b of the fourth semiconductor chip 400.

A third signal bump SB3 may be disposed between the third signal pillar SP3 and the third upper signal pad USP3 of the third semiconductor chip 300. A third center dummy bump DB3a may be disposed between the third center dummy pillar DP3a and the third upper center dummy pad UDP3a of the third semiconductor chip 300. A third corner dummy bump DB3b may be disposed between the third corner dummy pillar DP3b and the third upper corner dummy pad UDP3b of the third semiconductor chip 300.

A third chip adhesive layer 540 may be disposed between the third semiconductor chip 300 and the fourth semiconductor chip 400. The third chip adhesive layer 540 may substantially surround the third signal pillar SP3, the third signal bump SB3, the third center dummy pillar DP3a, the third center dummy bump DB3a, the third corner dummy pillar DP3b, and the third corner dummy bump DB3b. That is the third chip adhesive layer 540 may be substantially the same as the first chip adhesive layer 520.

The third signal pillar SP3 and the third signal bump SB3 may provide an electrical path between the fourth semiconductor chip 400 and the third semiconductor chip 300. That is, the third semiconductor chip 300 may be electrically connected to the fourth semiconductor chip 400 through the third signal pillar SP3 and the third signal bump SB3. The third center dummy pillar DP3a, the third center dummy bump DB3a, the third corner dummy pillar DP3b, and the third corner dummy bump DB3b are configured to provide a thermal path between the third semiconductor chip 300 and the fourth semiconductor chip 400. That is, the third center dummy pillar DP3a, the third center dummy bump DB3a, the third corner dummy pillar DP3b, and the third corner dummy bump DB3b are not configured to communicate an electrical signal, but may instead be configured to conduct (or transmit) heat generated by the first to fourth semiconductor chips 100 to 400 to an external heat sink, for example. Accordingly, the semiconductor package 1000 may exhibit improved heat dissipation performance by including the third center dummy pillar DP3a, the third center dummy bump DB3a, the third corner dummy pillar DP3b, and the third corner dummy bump DB3b.

Of note, the third signal pillar SP3, the third center dummy pillar DP3a, the third corner dummy pillar DP3b, the third signal bump SB3, the third center dummy bump DB3a, and the third corner dummy bump DB3b may be substantially the same as the first signal pillar SP1, the first center dummy pillar DP1a, the first corner dummy pillar DP1b, the first signal bump SB1, the first center dummy bump DB1a, and the first corner dummy bump DB1b, respectively.

A molding layer 510 may cover portion(s) of an upper surface of the first semiconductor chip 100 as well as sidewalls of the second to fourth semiconductor chips 200 to 400. The molding layer 510 may further cover sidewalls of the first to third chip adhesive layers 520 to 540. The molding layer 510 may include an insulating polymer or an epoxy resin. For example, the molding layer 510 may include an epoxy mold compound (EMC).

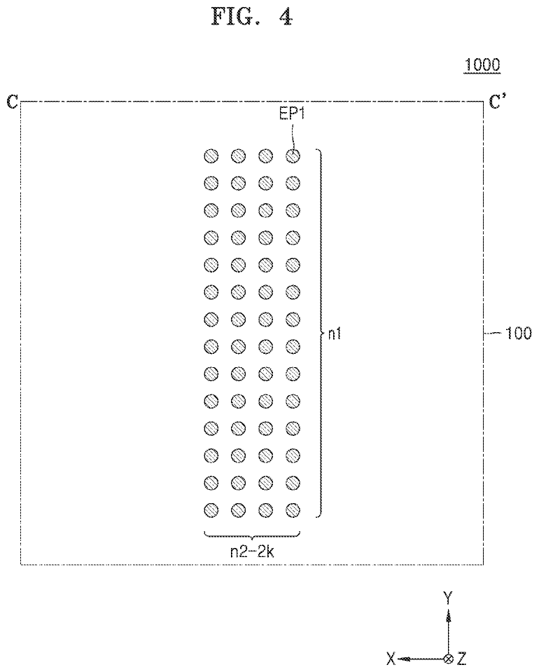

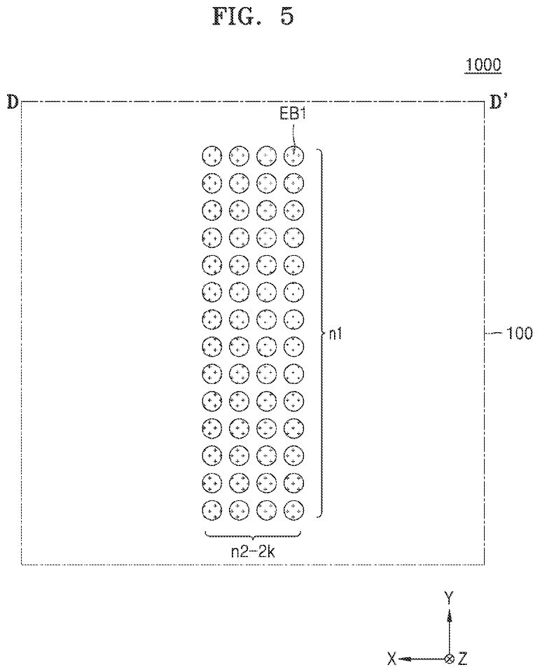

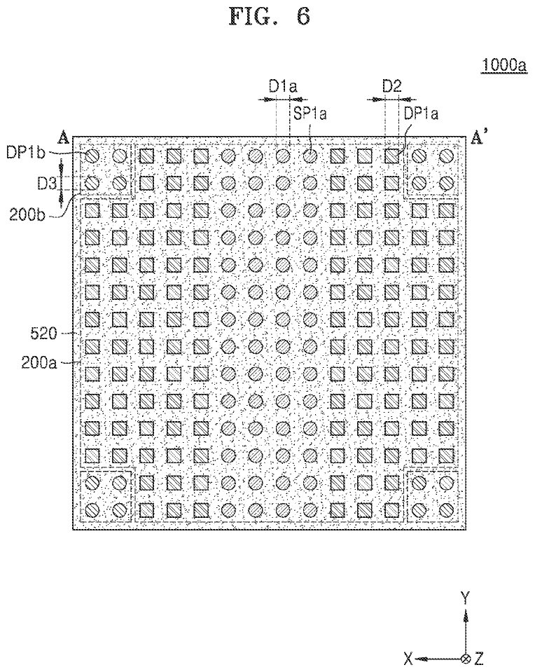

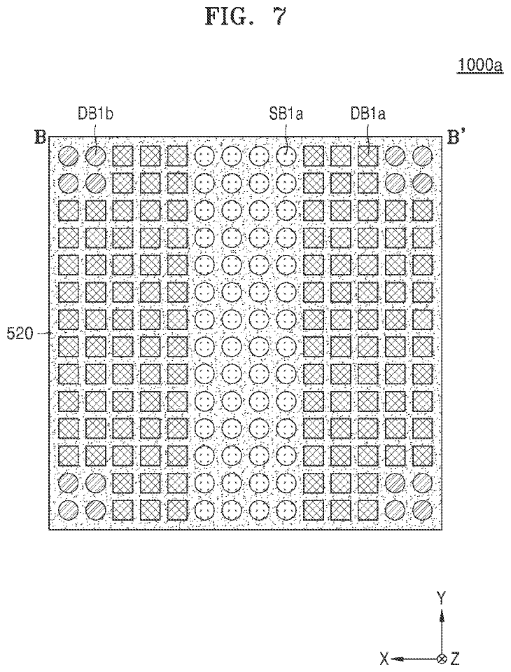

FIGS. 6 and 7 are respective cross-sectional views illustrating a semiconductor package 1000a according to embodiments of the inventive concept, wherein FIG. 6 corresponds to the cross-sectional view taken along line A-A′ in FIG. 1, and FIG. 7 corresponds to the cross-sectional view taken along line B-B′ in FIG. 1. Hereinafter, only material differences between the semiconductor package 1000 of FIGS. 1 to 5 and the semiconductor package 1000a of FIGS. 6 and 7 will be described.

Referring to FIGS. 6 and 7, a horizontal cross-section of the first signal pillar SP1a may be elliptical. That is, the first signal pillar SP1a may have a cylindrical shape. Also, as shown in FIG. 7, a horizontal cross-section of the first signal bump SB1a may be elliptical.

In some embodiments, a first diameter D1a of the first signal pillar SP1a, a width D2 of one side of the first center dummy pillar DP1a, and a second diameter D3 of the first corner dummy pillar DP1b may be substantially equal. By defining the side/diameter dimensions of the first signal pillar SP1a, the first center dummy pillar DP1a, and the first corner dummy pillar DP1b to be equal, an arrangement of the first signal pillar SP1a, the first center dummy pillar DP1a, and the first corner dummy pillar DP1b may be readily realized. And again, because the area of a quadrangle having a side length A is greater than the area of a circle having a diameter A, a cross-sectional area of the first center dummy pillar DP1a may be greater than a cross-sectional area of the first signal pillar SP1a.

In some embodiments, the first diameter D1a of the first signal pillar SP1a may range from between about 5 μm to about 20 μm. Here, when the first diameter D1a of the first signal pillar SP1a is greater than about 20 μm, the area occupied on the second semiconductor chip 200 may be too large. Yet, when the first diameter D1a of the first signal pillar SP1a is less than about 5 μm, an resulting electrical resistance of the first signal pillar SP1a may be too high.

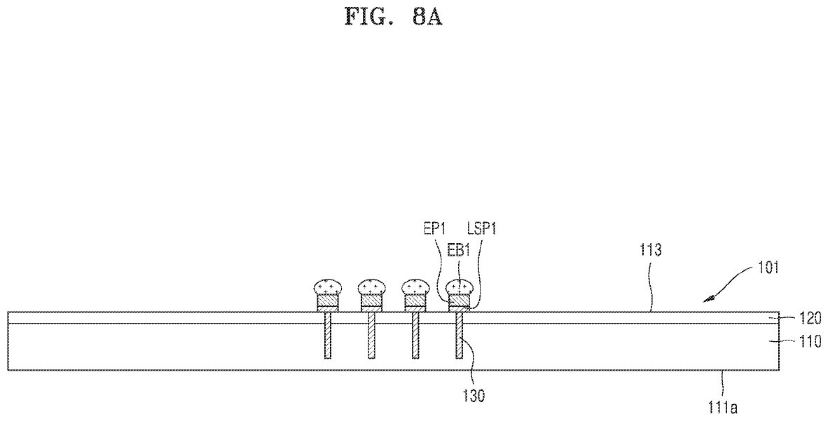

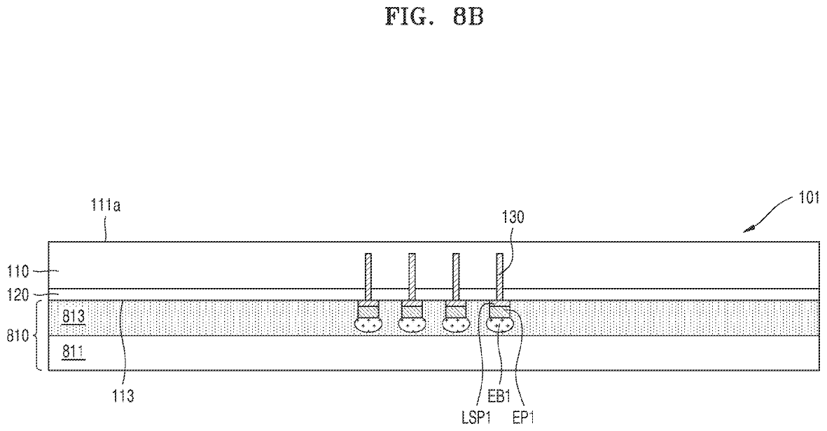

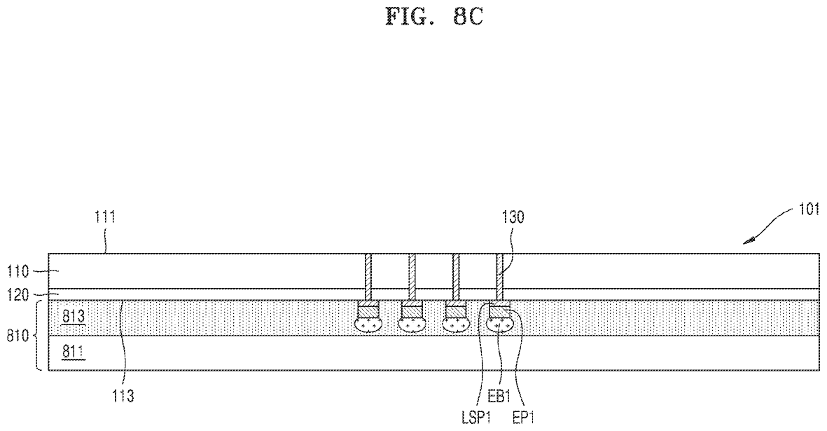

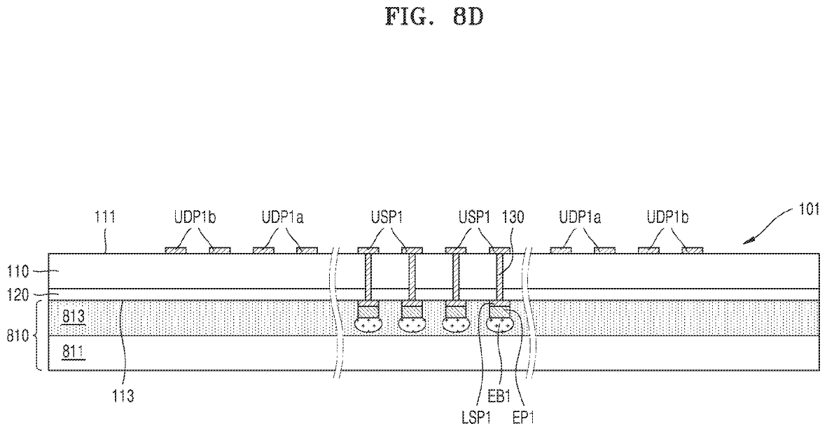

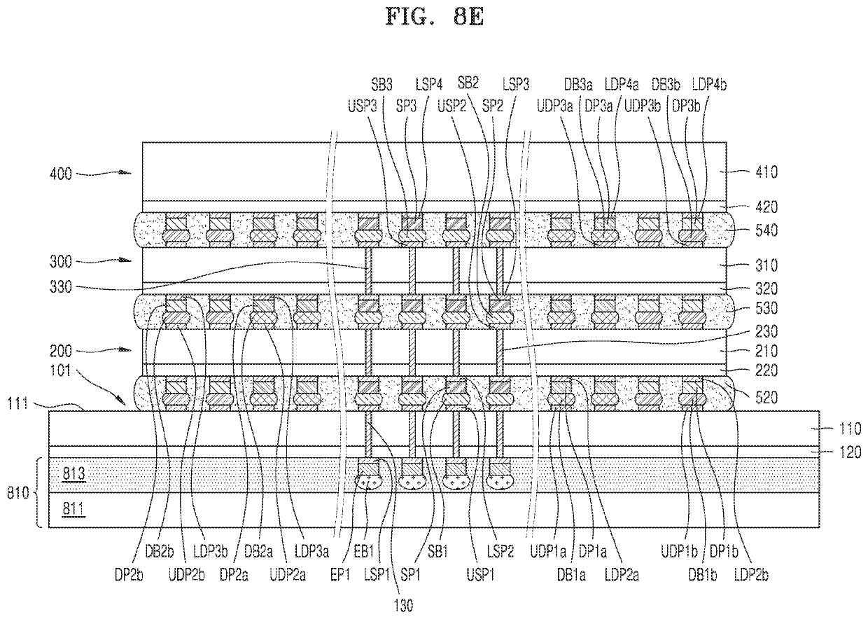

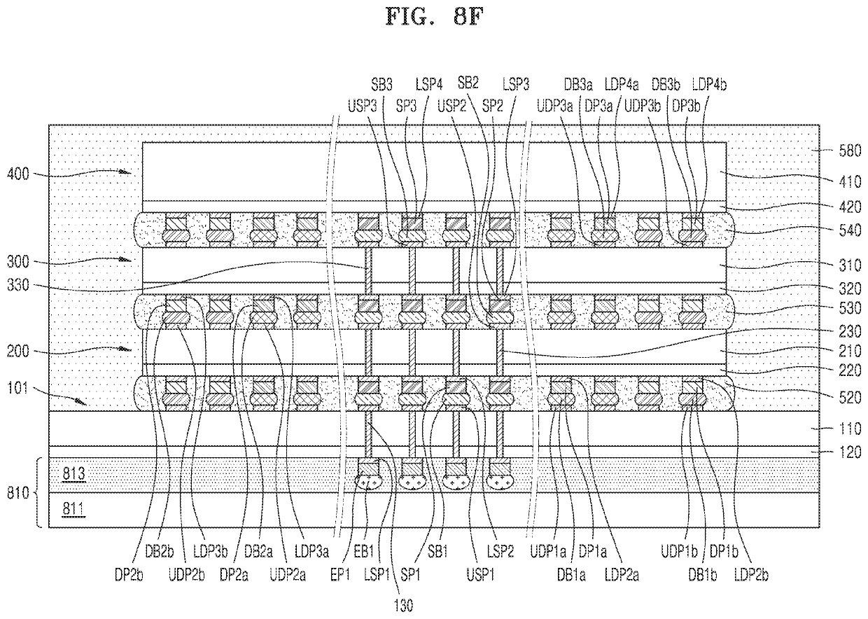

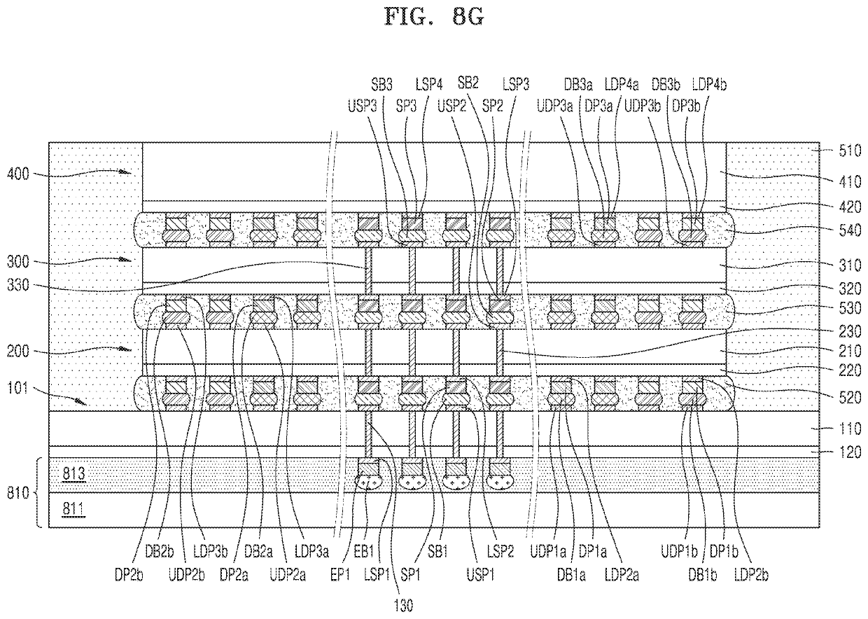

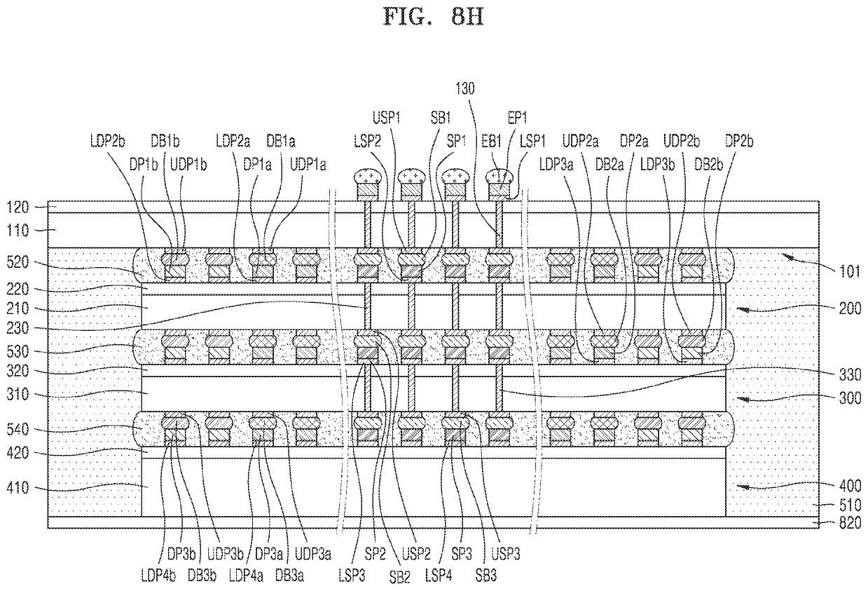

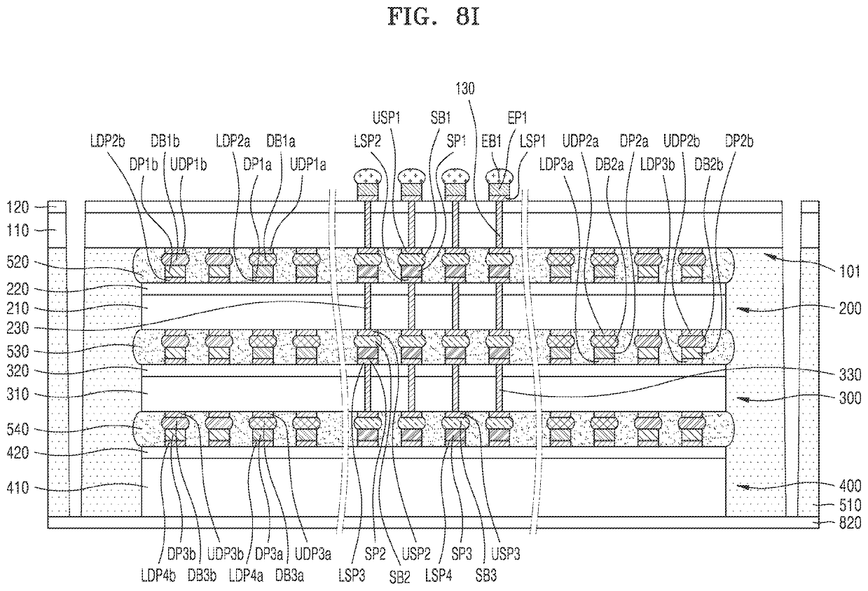

FIGS. 8A to 8I are related cross-sectional views illustrating in one example a method of manufacturing a semiconductor package according to embodiments of the inventive concept.

Referring to FIG. 8A, a first semiconductor wafer 101 is prepared. The first semiconductor wafer 101 includes a first semiconductor substrate 110, a first semiconductor device layer 120, a first through electrode 130, and a first lower signal pad LSP1. The first semiconductor wafer 101 includes a first surface 111a and a second surface 113. The first semiconductor device layer 120 may be formed on the first semiconductor substrate 110. The first through electrode 130 may be formed to penetrate the first semiconductor device layer 120 and extend into the first semiconductor substrate 110. The first lower signal pad LSP1 may be formed on the second surface 113 of the first semiconductor wafer 101.

Next, an external pillar EP1 on the first lower signal pad LSP1 and an external bump EB1 on the external pillar EP1 are formed.

Referring to FIG. 8B, the second surface 113 of the first semiconductor wafer 101 on which the external pillars EP1 and the external bumps EB1 are formed may be attached to a first carrier substrate 810. The first carrier substrate 810 may include a support substrate 811 and an adhesive material 813 on the support substrate 811.

Referring to FIGS. 8B and 8C, the first semiconductor substrate 110 may be removed from the first surface 111a side of the first semiconductor substrate 110 to expose the first through electrode 130. In order to expose the first through electrode 130, a portion of the first semiconductor substrate 110 may be removed by using a chemical mechanical polish (CMP) process, an etch-back process, or a combination thereof. As a result, a third surface 111 of the first semiconductor substrate 110 may be formed.

Referring to FIG. 8D, a first upper signal pad USP1, a first upper center dummy pad UDP1a, and a first upper corner dummy pad UDP1b may be formed on the third surface 111 of the first semiconductor substrate 110.

Referring to FIG. 8E, a second semiconductor chip 200 may be prepared. The second semiconductor chip 200 may include a second semiconductor substrate 210, a second semiconductor device layer 220, a second lower signal pad LSP2, and a second lower center dummy pad LDP2a, a second lower corner dummy pad LDP2b, a second upper signal pad USP2, a second upper center dummy pad UDP2a, a second upper corner dummy pad UDP2b, and a second through electrode 230.

A first signal pillar SP1 on the second lower signal pad LSP2, a first signal bump SB1 on the first signal pillar SP1, a first center dummy pillar DP1a on the second lower center dummy pad LDP2a, a first center dummy bump DB1a on the first center dummy pillar DP1a, a first corner dummy pillar DP1b on the second lower corner dummy pad LDP2b, and a first corner dummy bump DB1b on the first corner dummy pillar DP1b may be formed. The first signal pillar SP1, the first signal bump SB1, the first center dummy pillar DP1a, and the first center dummy bump DB1a may be patterned to have a quadrangular cross-section. The first corner dummy pillar DP1b and the first corner dummy bump DB1b may be patterned to have an elliptical cross-section. Alternately, the first signal pillar SP1 and the first signal bump SB1 may be patterned to have an elliptical cross-section.

The second semiconductor chip 200 may be stacked on the third surface 111 of the first semiconductor wafer 101 so that the first signal bump SB1, the first center dummy bump DB1a, and the first corner dummy bump DB1b are in contact with the first upper signal pad USP1, the first upper center dummy pad UDP1a, and the first upper corner dummy pad UDP1b, respectively. Also, a first chip adhesive layer 520 may be formed between the first semiconductor wafer 101 and the second semiconductor chip 200. In order to electrically connect the second semiconductor chip 200 to the first semiconductor wafer 101, a reflow process or a thermal compression process may be performed.

Next, a third semiconductor chip 300 may be prepared. The third semiconductor chip 300 may include a third semiconductor substrate 310, a third semiconductor device layer 320, a third lower signal pad LSP3, a third lower center dummy pad LDP3a, a third lower corner dummy pad LDP3b, a third upper signal pad USP3, a third upper center dummy pad UDP3a, a third upper center dummy pad UDP3b, and a third through electrode 330.

A second signal pillar SP2 on the third lower signal pad LSP3, a second signal bump SB2 on the second signal pillar SP2, a second center dummy pillar DP2a on the third lower center dummy pad LDP3a, a second center dummy bump DB2a on the second center dummy pillar DP2a, a second corner dummy pillar DP2b on the third lower corner dummy pad LDP3b, and a second corner dummy bump DB2b on the second corner dummy pillar DP2b may be formed. The second signal pillar SP2, the second signal bump SB2, the second center dummy pillar DP2a, and the second center dummy bump DB2a may be patterned to have a quadrangular cross-section. The second corner dummy pillar DP2b and the second corner dummy bump DB2b may be patterned to have an elliptical cross-section. Alternately, the second signal pillar SP2 and the second signal bump SB2 may be patterned to have an elliptical cross-section.

The third semiconductor chip 300 may be stacked on the second semiconductor chip 200 so that the second signal bump SB2, the second center dummy bump DB2a, and the second corner dummy bump DB2b are in contact with the second upper signal pad USP2, the second upper center dummy pad UDP2a, and the second upper corner dummy pad UDP2b, respectively. Also, a second chip adhesive layer 530 may be formed between the second semiconductor chip 200 and the third semiconductor chip 300. In order to electrically connect the third semiconductor chip 300 to the second semiconductor chip 200, a reflow process or a thermal compression process may be performed.

Next, a fourth semiconductor chip 400 may be prepared. The fourth semiconductor chip 400 may include a fourth semiconductor substrate 410, a fourth semiconductor device layer 420, a fourth lower signal pad LSP4, a fourth lower center dummy pad LDP4a, and a fourth lower corner dummy pad LDP4b.

A third signal pillar SP3 on the fourth lower signal pad LSP4, a third signal bump SB3 on the third signal pillar SP3, a third center dummy pillar DP3a on the fourth lower center dummy pad LDP4a, a third center dummy bump DB3a on the third center dummy pillar DP3a, a third corner dummy pillar DP3b on the fourth lower corner dummy pad LDP4b, and a third corner dummy bump DB3b on the third corner dummy pillar DP3b may be formed. The third signal pillar SP3, the third signal bump SB3, the third center dummy pillar DP3a, and the third center dummy bump DB3a may be patterned to have a quadrangular cross-section. The third corner dummy pillar DP3b and the third corner dummy bump DB3b may be patterned to have an elliptical cross-section. Alternately, the third signal pillar SP3 and the third signal bump SB3 may be patterned to have an elliptical cross-section.

The fourth semiconductor chip 400 may be stacked on the third semiconductor chip 300 so that the third signal bump SB3, the third center dummy bump DB3a, and the third corner dummy bump DB3b are in contact with the third upper signal pad USP3, the third upper center dummy pad UDP3a, and the third upper corner dummy pad UDP3b, respectively. Also, a third chip adhesive layer 540 may be formed between the third semiconductor chip 300 and the fourth semiconductor chip 400. In order to electrically connect the fourth semiconductor chip 400 to the third semiconductor chip 300, a reflow process or a thermal compression process may be performed.

Referring to FIG. 8F, a pre-molding layer 580 covering the second to fourth semiconductor chips 200 to 400 may be formed on the first semiconductor wafer 101.

Referring to FIGS. 8F and 8G, a portion of the pre-molding layer 580 may be removed to expose the fourth semiconductor chip 400. The portion of the pre-molding layer 580 may be removed through a planarization process such as CMP to expose the fourth semiconductor chip 400. As a result, a molding layer 510 may be formed from the pre-molding layer 580.

Referring to FIG. 8H, a second carrier substrate 820 may be attached on the molding layer 510 and the fourth semiconductor chip 400. For example, the second carrier substrate 820 may be a dicing film. The resultant product to which the second carrier substrate 820 is attached may be turned over, and then the first carrier substrate 810 may be removed from the first semiconductor wafer 101.

Referring to FIG. 8I, the semiconductor package 1000 as shown in FIG. 1 may be separated by cutting the result of FIG. 8H. After the semiconductor package 1000 is separated, the second carrier substrate 820 may be removed.

While the inventive concept has been particularly shown and described with reference to a variety of illustrated embodiments, it will be understood that various changes in form and details may be made therein without departing from the scope of the inventive concept as defined by the following claims.

What is claimed is:

1. A semiconductor package comprising:
a first semiconductor chip, and a second semiconductor chip stacked on the first semiconductor chip;
a chip adhesive layer between the first semiconductor chip and the second semiconductor chip;
a signal pillar having a quadrangular horizontal cross-section and a center dummy pillar having a quadrangular horizontal cross-section between a central portion of the second semiconductor chip and the first semiconductor chip;
a corner dummy pillar having an elliptical horizontal cross-section between a corner portion of the second semiconductor chip and the first semiconductor chip;
a signal bump between the signal pillar and the first semiconductor chip;
a center dummy bump between the center dummy pillar and the first semiconductor chip; and
a corner dummy bump between the corner dummy pillar and the first semiconductor chip,
wherein the signal pillar and the signal bump provide an electrical path between the second semiconductor chip and the first semiconductor chip,
the center dummy pillar and the center dummy bump provide one thermal path between the second semiconductor chip and the first semiconductor chip, and
the corner dummy pillar and the corner dummy bump provide another thermal path between the second semiconductor chip and the first semiconductor chip.

2. The semiconductor package of claim 1, wherein a cross-sectional area of the signal pillar is greater than a cross-sectional area of the corner dummy pillar.

3. The semiconductor package of claim 1, wherein a cross-sectional area of the center dummy pillar is greater than a cross-sectional area of the corner dummy pillar.

4. The semiconductor package of claim 1, wherein a first width of one side of the signal pillar is equal to a second width of one side of the center dummy pillar.

5. The semiconductor package of claim 1, wherein a second width of one side of the center dummy pillar is equal to a diameter of the corner dummy pillar.

6. The semiconductor package of claim 1, wherein the signal bump has a quadrangular horizontal cross-section, the center dummy bump has a quadrangular horizontal cross-section, and the corner dummy bump has an elliptical horizontal cross-section.

7. The semiconductor package of claim 1, wherein the second semiconductor chip further includes a lower signal pad contacting the signal pillar, a lower center dummy pad contacting the center dummy pillar, and a lower corner dummy pad contacting the corner dummy pillar, and
the first semiconductor chip further includes an upper signal pad contacting the signal bump, an upper center dummy pad contacting the center dummy bump, and an upper corner dummy pad contacting the corner dummy bump.

8. The semiconductor package of claim 1, wherein the first semiconductor chip includes a through electrode electrically connected to the signal bump.

9. The semiconductor package of claim 1, further comprising:
an external pillar having an elliptical horizontal cross-section on a lower surface of the first semiconductor chip; and
an external bump on the external pillar.

10. The semiconductor package of claim 1, wherein each of a first width of one side of the signal pillar, a second width of one side of the center dummy pillar, and a diameter of the corner dummy pillar equally range from about 5 μm to about 20 μm.

11. A semiconductor package comprising:
a first semiconductor chip and a second semiconductor chip stacked on the first semiconductor chip;
a chip adhesive layer between the first semiconductor chip and the second semiconductor chip;
signal pillars two-dimensionally arranged between a central portion of the second semiconductor chip and the first semiconductor chip;
center dummy pillars two-dimensionally arranged between the central portion of the second semiconductor chip and the first semiconductor chip;
corner dummy pillars two-dimensionally arranged between a corner portion of the second semiconductor chip and the first semiconductor chip;
signal bumps respectively between the signal pillars and the first semiconductor chip;
center dummy bumps respectively between the center dummy pillars and the first semiconductor chip; and
corner dummy bumps respectively between the corner dummy pillars and the first semiconductor chip,
wherein each of the signal pillars with one of the signal bumps provides an electrical paths between the second semiconductor chip and the first semiconductor chip,
each one of the center dummy pillars with one of the center dummy bumps provides a respective thermal path between the second semiconductor chip and the first semiconductor chip,
each one of the corner dummy pillars with one of the corner dummy bumps provides a respective thermal path between the second semiconductor chip and the first semiconductor chip,
each of the signal pillars and each of the center dummy pillars has a quadrangular horizontal cross-section, and
each of the corner dummy pillars has an elliptical horizontal cross-section.

12. The semiconductor package of claim 11, wherein a first pitch for the signal pillars is equal to a second pitch for the center dummy pillars.

13. The semiconductor package of claim 11, wherein a second pitch for the center dummy pillars is equal to a third pitch for the corner dummy pillars.

14. The semiconductor package of claim 11, wherein each of a first pitch for the signal pillars, a second pitch for the center dummy pillars, and a third pitch for the corner dummy pillars range from about 10 μm to about 40 μm.

15. The semiconductor package of claim 11, wherein the signal pillars, the center dummy pillars, and the corner dummy pillars are arranged in an array having n1 rows and n2 columns, wherein n1 and n2 are natural numbers.

16. The semiconductor package of claim 15, wherein the center dummy pillars and the corner dummy pillars are arranged in 1st to k-th columns and n2-k+1 to n2-th columns of the array, wherein k is a natural number.

17. The semiconductor package of claim 15, wherein the corner dummy pillars are arranged at positions of an m1-th row and an m2-th column of the array, and
m1 is (1 to j1) or (n1-j1+1 to n1),
m2 is (1 to j2) or (n2-j2+1 to n2), and
m1, m2, j1, j2 are respectively natural numbers.

18. A semiconductor package comprising:
a first semiconductor chip and a second semiconductor chip stacked on the first semiconductor chip;
a chip adhesive layer between the first semiconductor chip and the second semiconductor chip;
a signal pillar having an elliptical horizontal cross-section and a center dummy pillar having a quadrangular horizontal cross-section between a central portion of the second semiconductor chip and the first semiconductor chip;
a corner dummy pillar having an elliptical horizontal cross-section between a corner portion of the second semiconductor chip and the first semiconductor chip;
a signal bump between the signal pillar and the first semiconductor chip;
a center dummy bump between the center dummy pillar and the first semiconductor chip;
a corner dummy bump between the corner dummy pillar and the first semiconductor chip; and
a molding layer covering a portion of an upper surface of the first semiconductor chip and sidewalls of the second semiconductor chip,
wherein the signal pillar and the signal bump provide an electrical path between the second semiconductor chip and the first semiconductor chip,
the center dummy pillar and the center dummy bump provide one thermal path between the second semiconductor chip and the first semiconductor chip, and
the corner dummy pillar and the corner dummy bump provide another thermal path between the second semiconductor chip and the first semiconductor chip.

19. The semiconductor package of claim 18, wherein a cross-sectional area of the center dummy pillar is greater than a cross-sectional area of the signal pillar, and
a cross-sectional area of the center dummy pillar is greater than a cross-sectional area of the corner dummy pillar.

20. The semiconductor package of claim 19, wherein a first diameter of the signal pillar, a width of one side of the center dummy pillar, and a second diameter of the corner dummy pillar are equal.
